(19) United States
(12) Patent Application Publication
(10) Pub. No.: US 2004/0038119 A1
(43) Pub. Date: Feb. 26, 2004

(54) Device and method for converting heat and/or radiation energy into electric energy

(76) Inventor: Werner Henze, Isernhagen (DE)

Correspondence Address: WILLIAM COLLARD, COLLARD & ROE, P.C., 1077 NORTHERN BOULEVARD, ROSLYN, NY, 11576, US

(21) Appl. No.: 10/470,210

(22) PCT Filed: Mar. 20, 2001
(86) PCT No.: PCT/DE01/01081

(30) Foreign Application Priority Data
Feb. 15, 2001 (DE) 101069227

(51) Int. Cl. H01M 14/00; H01M 10/44; H01L 37/00

(52) U.S. Cl. 429/50; 429/101; 429/176; 136/205; 136/230

(57) ABSTRACT

A device for converting heat and/or radiation energy into electric energy. The device is comprised of a gastight chamber and at least one electrochemical cell arranged in said gastight chamber, which consists of an anode and a cathode, an electrolyte being placed between the former and the latter and the terminal leads being guided outward. The gastight chamber and the elctrochemical cell contain a gas or gas mixture, to which energy in the form of heat (Δ) and/or radiation (hν) can be fed, wherein the gas or gas mixture comprises a molecular and a dissociated fraction, the proportion of which depends on the temperature and produces a difference in potential between the anode and the cathode.

The present invention relates to a device for converting heat and/or radiation energy into electrical energy according to claim 1 and a method of converting heat and/or radiation energy into electrical energy according to claim 19.

The known methods of converting heat or radiation energy into electrical energy include the following:

power plants or emergency power systems, which generate kinetic energy using fuel-operated combustion engines, which is then converted into electrical energy using electrical generators,

power plants which operate thermal steam turbines, which then provide electrical energy when coupled with electrical generators,

solar cells and semiconductor photoelements, which are only able to convert a small part of the convertible radiation energy into electrical energy,

fuel elements, in which electrical energy and heat are generated using fuels, or

thermoelements, which provide electrical energy due to differently heated contact points of different metals.

The known methods typically have too small an efficiency, which is largely caused by heat losses and the use of mechanically moved parts, rotating parts, for example.

The present invention is based on the object of providing a device and a method for converting heat and/or radiation energy into electrical energy at a higher efficiency.

This object is achieved for a device for converting heat and/or radiation energy into electrical energy with the features of claim 1 and for a method for converting heat and/or radiation energy into electrical energy with the features of claim 19. Refinements and advantageous embodiments result from the particular subclaims.

According to the present invention, the device for converting heat and/or thermal energy into electrical energy includes a gas-tight chamber and at least one electrochemical cell, positioned in the gas-tight chamber, which includes an anode and a cathode, between which an electrolyte is located and to which the connection lines are connected. The gas-tight chamber and the electrochemical cell contain a gas or gas mixture, to which energy may be supplied in the form of heat and/or radiation, the gas or gas mixture including a molecular component and a dissociated component, whose ratio is a function of the temperature and which generate a potential difference between anode and cathode.

A construction of this type allows the electrochemical cell positioned in the gas-tight chamber to continuously provide current in that the substances to be oxidized and the oxidants, which are obtained from the dissociation of the gas or gas mixture contained in the gas-tight chamber through continuous supply of heat and/or radiation energy, are continuously supplied to the electrochemical cell, and the oxidation products are continuously removed from the electrochemical cell into the gas-tight chamber, where they are again available as a gas which may be cleaved.

Therefore, in the event of current flow, a circular process arises in which only energy is supplied to the system in the form of heat and/or radiation.

Such a device has a very high efficiency, since the heat and/or radiation energy supplied is absorbed in the form of chemical energy and then converted into electrical energy in electrochemical ways.

An advantageous embodiment of the present invention provides that the gas-tight chamber contains hydrogen halide (HX), preferably hydrogen bromide (HBr) or hydrogen iodine (HI), which reversibly decomposes into hydrogen (H₂) and halogen (X₂) if heat and/or radiation is supplied.

Therefore, hydrogen (H₂) forms the substance to be oxidized and the halogen (X₂) forms the oxidant. Both reactants are obtained from the reversible cleavage of the hydrogen halide (HX) contained in the gas-tight chamber by supplying energy in the form of heat and/or radiation.

The overall reaction then occurring at the two electrodes of the electrochemical cell, H₂+X₂->2 HX, dissociates into an anode reaction and a cathode reaction.

The cathode preferably includes a material which, as an electronic acceptor, intercalates halogen molecules (X₂), partially as X₂⁻ anions and partially as X₂ molecules, between its crystal lattice layers, and the anode includes a material which dissociatively adsorbs the hydrogen (H₂) and absorbs the hydrogen atoms (H) thus arising.

In this way, the halogen (X₂) accepts one electron per atom at the cathode in the event of current flow (X₂+2e⁻->2X⁻, cathodic reduction). Subsequently, the halogen ions (X⁻), which carry one negative charge, exit from the cathode into the electrolyte, which is in contact therewith. The hydrogen (2H), in contrast, donates one electron per atom at the anode in the event of current flow (2H->2H⁺+2e⁻, anodic oxidation). The hydrogen ions (H⁺), which carry one positive charge, subsequently exit from the anode into the electrolyte, which is in contact therewith.

Finally, hydrogen halide, which dissipates into the gas-tight chamber, forms directly or indirectly in the electrolyte (H⁺+X⁻->HX).

The surfaces of the cathode and the anode, which are in contact with the gas in the gas-tight chamber, have catalytic effects in regard to the decomposition process of the hydrogen halide in different ways.

The catalytic effect of the cathodes is that in the event of current flow, X₂ molecules are released to the electrolytes as X⁻ ions and new X₂ molecules from the gas chamber are intercalated into the crystal lattice of the cathode.

Since the degree of decomposition of the hydrogen halide is a function of the temperature, a new component of the hydrogen halide must decompose if the temperature is kept constant, so that the molecules removed from the gas chamber may be replaced. If the temperature is not kept constant, i.e., no energy is supplied from the outside, the quantity of X₂ molecules removable from the gas chamber will be reduced and therefore the electrical energy which may be supplied will be also. However, the decomposition of the hydrogen halide will be excited at any temperature by the application of current through the catalytically acting cathodes and the recombination will be inhibited.

The catalytic effect of the anode is that hydrogen molecules (H₂) are adsorbed by the surface of the anode and partially dissociate into hydrogen atoms (H). As a function of the current flow, a part of the hydrogen atoms (H) are absorbed by the anode and another part causes a further cleavage of hydrogen halide molecules (HX). The decomposition of the hydrogen halide is therefore also excited by the catalytically acting anode and the recombination is inhibited.

The cathode is preferably made of graphite.

Graphite has good electrical conductivity and reacts with halogen molecules (X₂) to form an intercalation compound, in which the molecules reach the electrolytes in electrochemical ways. Furthermore, graphite is chemically resistant to halogen molecules (X₂), acids, and bases and has an increased temperature stability and no solubility in water. In addition, graphite is relatively cost-effective.

In a further embodiment of the present invention, the anode is made of iron (II, III) oxide (Fe₃O₄)

Iron (II, III) oxide (Fe₃O₄), which is also referred to as magnetic iron ore or hammer scale, has good electrical conductivity in relation to other oxides, absorbs, due to its dissociative adsorption of hydrogen molecules (H₂) on its surface, hydrogen atoms (H) for electrochemical relay to the electrolyte, and has chemical resistance to halogen molecules (X₂), elevated temperature stability, and no solubility in water. Furthermore, iron (II, III) oxide (Fe₃O₄) is relatively cost-effective and also acts catalytically.

Instead of iron (II, III) oxide (Fe₃O₄), platinum (Pt) or palladium (Pd) are also usable as an anode. However, these noble metals are relatively expensive. Other metallic oxides such as Cu₂O, ZnO, and TiO₂ only partially fulfill the requirements placed on a catalytically acting anode.

It is also advantageous that the relatively good electrical conductivity of iron (II, III) oxide (Fe₃O₄) increases further with increasing temperature.

In addition, to improve the conductivity of the anode, a thin graphite layer or a graphite conductive lattice and/or a layer made of a graphite/Fe₃O₄ mixture may be positioned between the electrolyte and the surface, which is made of iron (II, III) oxide (Fe₃O₄) and which faces the gas chamber.

In regard to the crystal lattice structure, iron (II, III) oxide (Fe₃O₄) is similar to the cubic close packing of atoms preferred by metals, which have octahedral and tetrahedral gaps, and therefore may absorb atomic hydrogen (H), i.e. may intercalate it. Iron (II, III) oxide (Fe₃O₄) has an inverse spinel lattice structure with the cubically closest packing of O₂⁻ ions and Fe²⁺ ions in octahedral gaps, Fe³⁺ ions half in tetrahedral gaps and the other half in octahedral gaps. Atomic hydrogen (H) may be intercalated in the remaining gaps. The hydrogen absorption may also occur in the octahedral gaps at elevated temperature.

Iron (II, III) oxide (Fe₃O₄) therefore has the property of absorbing hydrogen in atomic form.

It is advantageous that a reaction of the absorbed and/or intercalated hydrogen atoms with Fe₃O₄ first occurs at red heat (approximately 600° C.), in accordance with the following reaction equation:

Fe₃O₄+8H->3Fe+4H₂O

A refinement provides that the anode and the cathode have a large surface.

If the electrode surfaces are increased, besides the elevation of the quantity of the decomposable gases (X₂) and (H₂) removable from the gas-tight chamber, the catalytic influence of the electrodes on the decomposition of the hydrogen halide (HX) in the gas-tight chamber is also increased.

An advantageous embodiment of the present invention provides that the connection lines running inside the gas-tight chamber include a halogen-resistant electrical conductor, particularly graphite.

In addition, the gas-tight chamber is a halogen-resistant vessel.

The vessel preferably includes a radiation-transparent and thermally-insulating hood and a heat-transparent floor.

Due to the low thermal conductivity of the hood, heat energy supplied through the floor and/or heat arising through radiation energy is largely prevented from being dissipated to the surroundings again. In order to increase the efficiency of the device according to the present invention, it is advantageous to design the surroundings of the cell in such a way that an accumulation of heat arises.

The hood is preferably made of glass and the floor is preferably made of glass ceramic.

A refinement of the cell provides that the electrochemical cell is surrounded by a film, preferably made of polytetrafluoroethylene, PTFE (trade name Teflon, for example), which is gas-permeable, halogen-resistant, water-repellent, and electrically non-conductive.

This film also prevents the electrolytes from reaching the gas-tight chamber. Depending on the composition of the electrolytes, a gas pressure results in the sealed gas chamber as a function of the existing temperature. If the electrolyte is made, for example, of an azeotropic mixture of hydrogen bromide (HBr) and water, a gas pressure of 1 bar is reached inside the device according to the present invention at 124.3° C.

Teflon also has the property of inhibiting the reformation of atomic hydrogen (H) into hydrogen molecules (H₂). In this way, the absorption of atomic hydrogen (H) in the boundary region between the Teflon and Fe₃O₄ layers in the electrodes is encouraged.

It is advantageous that the temperature stability of Teflon reaches from −270° C. to +260° C. and Teflon is also not soluble in water.

Teflon is partially replaceable by silicone, since silicone is also water-repellent and chemically resistant. In addition, like Teflon, it inhibits the reformation of atomic hydrogen into hydrogen molecules.

In addition, the surface of the anode may be made of a mixture of Fe₃O₄ and Teflon, for example.

The part of the Teflon layer positioned over the electrolytes is preferably permeable to hydrogen halides (HX).

In this way, the electrochemical cell continuously generates current, because the oxidation product (HBr) is continually withdrawn from it and it may only escape into the gas-tight chamber.

A halogenide dissolved in water, particularly aluminum halogenide, is suitable as the electrolyte.

Aluminum halogenides react with water extremely vigorously according to the reaction equation

Al₂X₆+2H₂O->2X₃Al—OH₂ X=Br or I, for example

If there is only a little water present, then the complex formed stabilizes first through hydrogen halide cleavage, which leads to the halogenides XAl(OH)₂ and/or AlOX or to the hydroxide and/or oxide.

X₃Al—OH₂->X₂Al—OH+HX

This process may be repeated twice.

X₂Al—OH+H₂O->XAl(OH)₂+HX

XAl(OH)₂+H₂O->Al(OH)₃+HX

and/or

X₂Al—OH->AlOX+HX

AlOX+2H₂O->Al(OH)₃+HX

In contrast, if there is a sufficiently large excess of water, then the covalent halogenides dissociate completely into solvated ions.

Al₂X₆+>+6H₂O->[Al(OH₂)₆]₂X₆

Aqueous aluminum halogenide solutions represent real “salt solutions” having electrical conductivity. The reaction is not reversible, so that aluminum hydroxide (Al(OH)₃) and hydrogen halide (HX) form upon heating.

[Al(OH₂)₆]X₆−6H₂O->2Al(OH)₃+6HX

A magnesium halogenide dissolved in water may also be used as the electrolyte. The tendency toward hydrolysis is, however, lower than with aluminum halogenides. Upon heating, hydrogen halide escapes instead of water

MgX₂+H₂O⇄Mg(OH)X+HX

Mg(OH)X+H₂O->Mg(OH)₂+HX

A halogenic acid such as bromic acid or iodic acid is also usable as the electrolyte.

It is advantageous to use an azeotropic mixture of hydrogen halide (HX) and water (H₂O), it being ensured in the manufacturing of the device according to the present invention that only hydrogen halide (HX) is located in the gas-tight chamber. Hydrogen halide (HX) is then preferably provided in excess in relation to its solubility in water (H₂O). Since hydrogen halide (HX) is formed in the electrolyte in the event of current flow, it must also escape again into the gas-tight chamber. Therefore, the mixing ratio of the azeotropic mixture readjusts itself. Water may therefore not escape into the gas chamber. Enclosing the cell using a Teflon film, for example, is not necessary in this case. In addition, a water component in the gas-tight chamber only has a slight effect on the conductivity of the device according to the present invention, because the surfaces of the electrodes are thus also slightly in contact with water vapor. However, the cathode made of graphite is water repellent and the surface of the anode made of Fe₃O₄ is not soluble in water. The catalytic effects of the electrodes are maintained. In addition, water vapor first decomposes into hydrogen and oxygen at 1200° C. in a quantity of 10⁻³%, for example.

In a refinement, the electrolyte is situated in the pores of a silicon carbide disk.

This disk ensures mechanical stability and is additionally used as an electrode carrier.

According to the present invention, the method of converting heat and/or radiation energy according to claim 19 is distinguished in that

a) the hydrogen halide (HX) contained in the gas-tight chamber is reversibly cleaved into hydrogen (H₂) and halogen (X₂) by supplying energy in the form of heat and/or radiation,

b) the halogen (X₂) from the gas-tight chamber is intercalated in the crystal lattice of the cathode of the electrochemical cell and one electron is accepted per atom in the event of current flow (X₂+2e⁻->2X⁻, cathodic reduction),

c) the halogen ions (X⁻), which carry one negative charge, exit from the cathode into the electrolyte, which is in contact therewith,

d) the hydrogen molecules (H₂) are adsorbed, dissociated, and absorbed by the anode and, in the event of current flow, donate one electron per atom (2H->2H⁺+2e⁻, anodic oxidation),

e) the hydrogen ions (H⁺), which carry one positive charge, enter the electrolyte from the anode, which is in contact therewith,

f) hydrogen halide (H⁺+X⁻->HX) forms directly or indirectly in the electrolyte, and then passes into the gas-tight chamber, and

g) the steps a) to f) repeat in the event of current flow.

For continuous power generation, hydrogen (H₂) and halogen (X₂) are continuously supplied to the electrochemical cell and hydrogen halide (HX) is continuously removed from the electrochemical cell.

A refinement provides that energy is continuously supplied to the gas-tight chamber in the form of heat and/or radiation in order to maintain a specific equilibrium state.

In addition, hydrogen bromide (HBr) or hydrogen iodide (HI) is used as the hydrogen halide (HX).

Preferably, a halogen-resistant vessel is used as the gas-tight chamber, via whose walls heat and/or radiation energy is supplied.

In a refinement, the vessel includes a radiation-transparent and thermally-insulated hood and a heat-transparent floor, radiation energy mainly being supplied via the hood and heat energy mainly being supplied via the floor.

In the following, the present invention is described on the basis of an exemplary embodiment which is illustrated in the drawing.

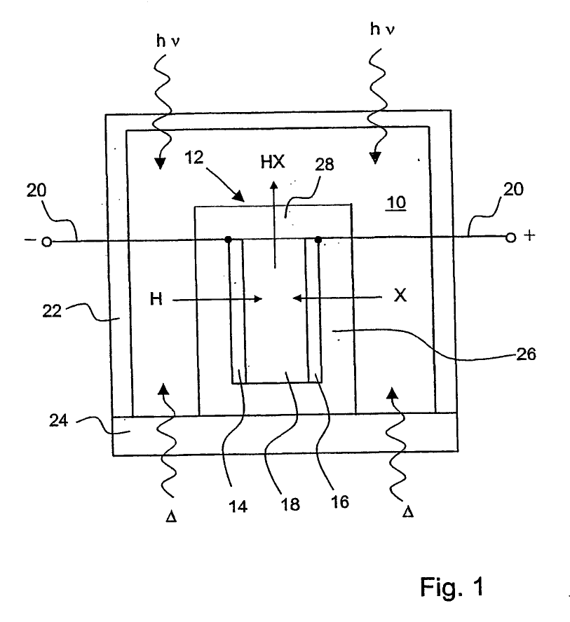

FIG. 1 shows a schematic illustration of the device according to the present invention,

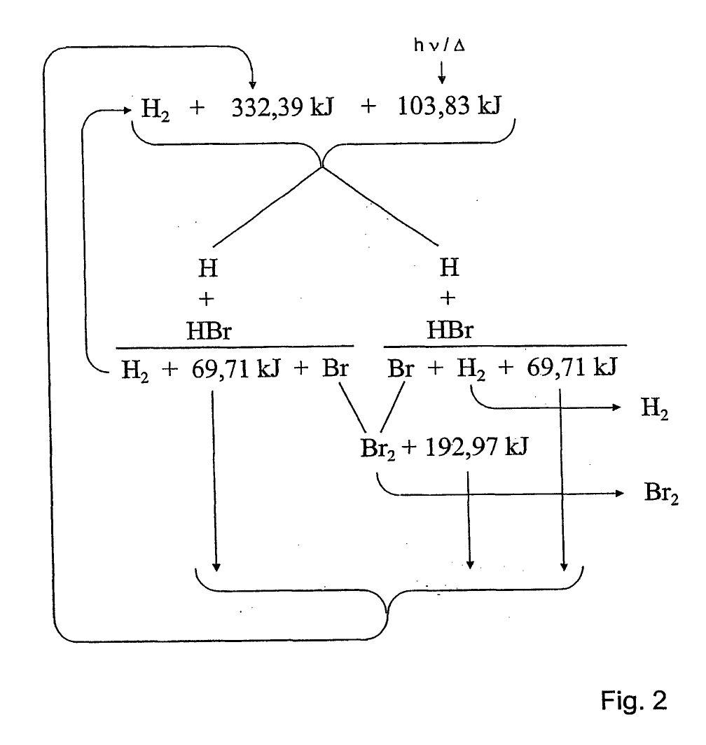

FIG. 2 shows the cleavage process for hydrogen bromide (HBr) inside the gas-tight chamber of the device according to the present invention, and

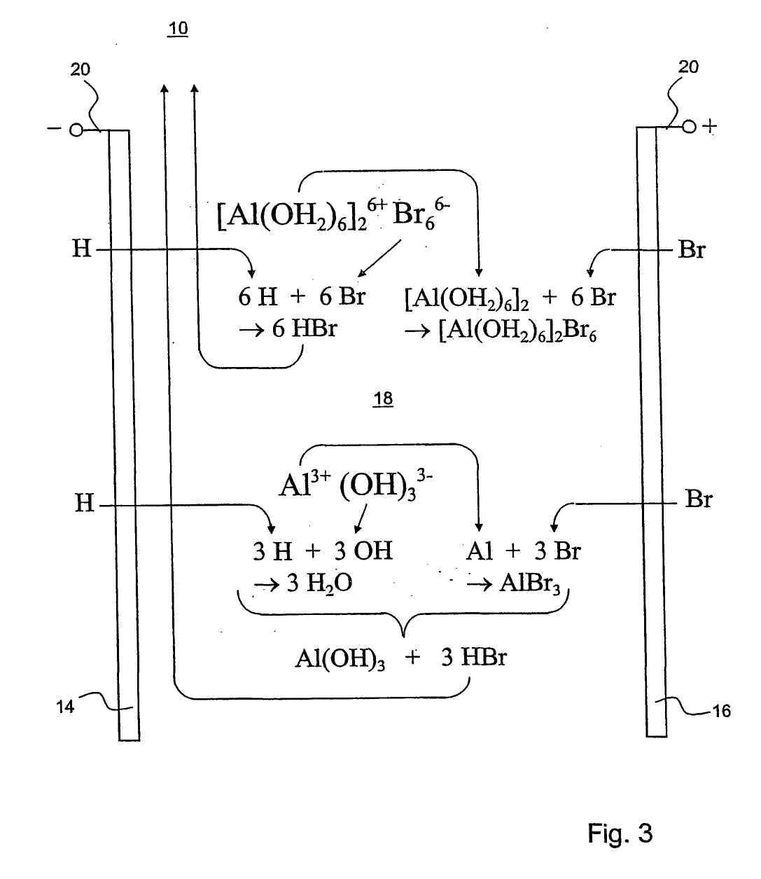

FIG. 3 shows the formation of hydrogen bromide (HBr) in the electrolyte of the device according to the present invention.

The construction of a device for converting heat and/or radiation energy (Δ, hν) into electrical energy is illustrated in FIG. 1.

The electrochemical cell 12 includes an anode 14, an electrolyte 18, and a cathode 16, and is positioned in a gas-tight, halogen-resistant vessel, which includes a radiation-transparent and thermally-insulated hood 22 and a heat-transparent floor 24.

Anode 14 and cathode 16 are connectable via a resistor using connection lines 20 to achieve a current flow.

The hood 22 of the vessel may be made of glass and the floor 24 of the vessel may be made of glass ceramic, radiation energy (hν) mainly being supplied via the hood 22 and heat energy (Δ) mainly being supplied via the floor 24.

The heat and/or radiation energy (Δ, hν) supplied to the gas-tight chamber 10 causes the hydrogen halide (HX) contained in the gas-tight chamber 10 to be reversibly cleaved into hydrogen (H₂) and halogen (X₂).

Since the reaction is reversible and may run in both directions, a specific equilibrium results between hydrogen (H₂), halogen (X₂), and hydrogen halide (HX) in the gas-tight chamber 10 at any temperature.

The electrochemical cell 12 positioned in the vessel is surrounded by a film 26, preferably made of Teflon (PTFE), which is gas-permeable, halogen-resistant, water-repellent, and electrically non-conductive, and which separates the electrolyte 18 from the gas-tight chamber 10.

The conversion of heat and/or radiation energy (Δ, hν) into electric energy begins with the cleavage of hydrogen halide (HX) into hydrogen (H₂) and halogen (X₂) by supplying energy in the form of heat (Δ) and/or radiation (hν).

The molar amount of energy which must at least be used for cleavage is indicated for exemplary purposes for hydrogen bromide (HBr) and hydrogen iodide (HI) in the following reaction equation:

$$\begin{matrix}2 HBr + 103.8 kJ {⟷}^{Δ , h ν} {H}_{2} + {Br}_{2} \\ 2 HI + 9.46 kJ {⟷}^{Δ , h ν} {H}_{2} + {I}_{2}\end{matrix}$$

In these reactions, an equilibrium state between decomposition and recombination of the hydrogen halide molecules (HX) results in the gas-tight chamber as a function of temperature.

For example, at 300° C., 19% of the hydrogen iodide molecules (HI) are always cleaved, and at 1000° C., 33% of the molecules are always cleaved. The proportion of cleaved hydrogen halide molecules (HX) increases with increasing temperature.

The cleaved component of the hydrogen halide (HX) is used for electrochemical conversion into electrical energy and is therefore to be as large as possible.

This may be achieved if the hydrogen halide (HX) is subjected to radiation (hν) and/or is in contact with catalytically active electrode surfaces, for example. In any case, the decomposition process of the hydrogen halide (HX) is thus favored over recombination, and the degree of decomposition in relation to the temperature is therefore increased. In this way, the device according to the present invention may begin to operate even at room temperature with a slight energy supply.

In the case of hydrogen iodide molecules (HI), cleavage (photodissociation) already begins to occur at 140° C., if they are irradiated at a light wavelength of 578 nm (green/yellow), which causes cleavage of the iodine molecules (I₂) (I₂->2I). In general, the quanta of visible light are only sufficient for those procedures whose molar reaction requires no more than 300 kJ of free energy. In addition, radiation energy (hν) may be converted very easily into heat energy (Δ), so that it may be optimally used in any case.

The side of the anode 14 facing the gas-tight chamber 10 directly adjoins the film 26.

The electrodes 14, 16 are electrochemically used as gas electrodes, the anode 14 representing a hydrogen electrode and the cathode 16 representing a halogen electrode. Correspondingly, the anode 14 forms the negative pole and the cathode 16 forms the positive pole.

By using suitable different materials for the electrodes 14, 16, it is ensured that the decomposition products hydrogen (H₂) and halogen (X₂) of the hydrogen halide (HX) located in the gas-tight chamber 10 are supplied separately to the electrolyte.

The halogen (X₂) accepts one electron per atom at the cathode 16 in the event of current flow (X₂+2e⁻->2X⁻, cathodic reduction). Subsequently, the halogen ions (X⁻), which carry one negative charge, enter the electrolyte 18 from the cathode 16, which is in contact therewith. In contrast, the hydrogen (2H) donates one electron per atom at the anode 14 in the event of current flow (2H->2H⁺+2e⁻, anodic oxidation). The hydrogen ions (H⁺), which carry one positive charge, subsequently enter the electrolyte 18 from the anode 14, which is in contact therewith.

Finally, hydrogen halide (H⁺+X⁻->HX), which escapes into the gas-tight chamber 10, forms in the electrolyte 18.

FIG. 2 shows the cleavage of hydrogen iodide (HBr) caused in the gas-tight chamber 10 by supplying heat and/or radiation energy (Δ, hν).

Starting from the cleavage of a hydrogen molecule (H₂), first hydrogen bromide (HBr) is cleaved into hydrogen (H₂) and bromine (Br) using the resulting atomic hydrogen atoms (2H). This reaction is reversible.

Furthermore, it is shown how the cleavage process of the hydrogen bromide (HBr) is maintained while energy is supplied (Δ, hν) through repeated cleavage of the decomposition product hydrogen (H₂).

However, at any temperature which is reached, an equilibrium state results through the recombination according to the reaction equation

H+Br₂->HBr+Br+173.50 kJ,

in which a very specific proportion of the hydrogen bromide (HBr) is cleaved.

The molar amount of energy which must at least be used for cleavage is 103.83 kJ for hydrogen bromide (HBr).

According to the principle of mass action, this state is maintained as long as no energy supply, heat dissipation, removal of the cleavage products hydrogen (H₂) and halogen (X₂), or reduction of the hydrogen bromide component occurs.

Since, however, in the electrochemical process shown in FIG. 3, the cleavage products hydrogen (H₂) and bromine (Br₂) are continuously removed from the gas-tight chamber 10 and hydrogen bromide (HBr) is resupplied, energy (Δ, hν) must be continuously supplied to the gas-tight chamber 10 in order to maintain a specific equilibrium state at a constant temperature.

FIG. 3 shows the formation of hydrogen bromide (HBr) in the electrolyte 18. The electrolyte 18 is an aqueous aluminum bromide solution, from which the hydrogen bromide (HBr) formed may escape into the gas-tight chamber 10 shown in FIG. 1.

The proportion of water selected in the electrolyte 18 is large enough that a sufficiently large excess of water is present.

If the proportion of water falls below this limit, a correspondingly large amount of aluminum hydroxide (Al(OH)₃) is formed and the associated proportion of hydrogen bromide (HBr) escapes into the gas-tight chamber 10. In the event of excess, hydrogen bromide (HBr) is partially dissolved in the excess water component.

Therefore, it must be assumed that solvated ions of the aluminum halogenide and the ions of the aluminum hydroxide take part in the process.

Since the water component in the electrolyte 18 remains constant and the concentrations of the dissolved aluminum bromide (AlBr₃) and the aluminum hydroxide (Al(OH)₃) also do not change, the electrochemically formed hydrogen bromide (HBr) will again escape into the gas-tight chamber 10.

For this purpose, the part 28 of the film 26 over the electrolyte 18 shown in FIG. 1 is permeable to hydrogen halide (HX).

As soon as electrical energy is removed via the connection lines 20 and current therefore flows, hydrogen (H₂) and halogen (X₂) are withdrawn from the gas-tight chamber 10 and supplied to the electrochemical cell 12. Hydrogen halide (HX) is formed as a product in the electrolyte 18, which then passes into the gas-tight chamber 10 and is again decomposed there into hydrogen (H₂) and halogen (X₂) by supplying energy in the form of heat (Δ) and/or radiation (hν).

Therefore, a closed loop of the hydrogen halide (HX) exists, through which heat and radiation energy (Δ, hν) are converted into electrical energy at a high degree of efficiency. Heat energy losses, which may be traced back to the internal resistance of the electrochemical cell, for example, will not result, because any contribution to the heat energy increases the temperature and therefore raises the degree of decomposition of the hydrogen halide (HX) in the gas-tight chamber 10.

The terminal voltage arising on the connection lines 20 is nominally 1.06 V if bromine is used as the halogen with an acid electrolyte, such as bromic acid or aluminum bromide dissolved in water, and is 0.53 V for an acid iodine electrolyte.

1. A device for converting heat and/or radiation energy (Δ, hν) into electrical energy, including a gas-tight chamber (10) and at least one electrochemical cell (12), positioned in the gas-tight chamber (10), which includes an anode (14) and cathode (16), between which an electrolyte (18) is located and to which the connection lines (20) are connected, wherein the gas-tight chamber (10) and the electrochemical cell (12) contain a gas or gas mixture, to which energy may be supplied in the form of heat (Δ) and/or radiation (hν), and the gas or gas mixture includes a molecular component and a dissociated component, whose ratio is a function of the temperature and which generates a potential difference between the anode (14) and the cathode (16).

2. The device according to claim 1, characterized in that the gas-tight chamber (10) contains hydrogen halide (HX), preferably hydrogen bromide (HBr) or hydrogen iodide (HI), which reversibly decomposes into hydrogen (H₂) and halogen (X₂) when energy is supplied in the form of heat (Δ) and/or radiation (hν).

3. The device according to claim 1 or 2, characterized in that the cathode (16) includes a material which ionically binds halogen (X₂) and intercalates it in its crystal lattice, and the anode (14) includes a material which adsorbs and absorbs hydrogen (H₂, H).

4. The device according to claim 2 or 3, characterized in that the hydrogen (H₂) may be cleaved on the surface of the anode (14) through dissociative adsorption.

5. The device according to claim 4, characterized in that a catalyst is provided which inhibits the reformation of the resulting atomic hydrogen (H) into hydrogen molecules (H₂).

6. The device according to one of claims 1 to 5, characterized in that the cathode (16) and anode (14) are designed as thin-film.

7. The device according to one of claims 1 to 6, characterized in that the cathode (16) includes graphite.

8. The device according to one of claims 1 to 7, characterized in that the anode (14) includes iron (II, III) oxide (Fe₃O₄), platinum (Pt), or palladium (Pd).

9. The device according to one of claims 1 to 8, characterized in that the anode (14) and cathode (16) have large surfaces.

10. The device according to one of claims 1 to 9, characterized in that the connection lines (20) running inside the gas-tight chamber (10) include a halogen-resistant electrical conductor, particularly graphite.

11. The device according to one of claims 1 to 10, characterized in that the gas-tight chamber (10) is a halogen-resistant vessel.

12. The device according to claim 11, characterized in that the vessel includes a radiation-transparent and thermally-insulated hood (22) and a heat-transparent floor (24).

13. The device according to claim 12, characterized in that the hood (22) is made of glass and the floor (24) is made of glass ceramic.

14. The device according to one of claims 1 to 13, characterized in that the electrochemical cell (12) is enclosed by a film (26), particularly made of Teflon, which is gas-permeable, halogen-resistant, water-repellent, and electrically non-conductive.

15. The device according to claim 14, characterized in that the part (28) of the film (26) positioned over the electrolyte (18) is permeable to hydrogen halide (HX).

16. The device according to one of claims 1 to 15, characterized in that the electrolyte (18) includes a halogenide dissolved in water (H₂O), particularly aluminum halogenide (AlBr₃).

17. The device according to one of claims 1 to 16, characterized in that the electrolyte (18) is made of an azeotropic mixture of hydrogen halide (HX) and water (H₂O).

18. The device according to one of claims 1 to 17, characterized in that the electrolyte (18) is positioned in the pores of a halogen-resistant material, particularly a silicon carbide disk.

19. A method of converting heat and/or radiation energy into electrical energy, characterized in that
a) a hydrogen halide (HX) contained in a gas-tight chamber (10) is reversibly cleaved into hydrogen (H₂) and halogen (X₂) by supplying energy in the form of heat (Δ) and/or radiation (hν),
b) the halogen (X₂) is intercalated in the cathode (16) of an electrochemical cell (12) positioned in the gas-tight chamber (10) and accepts one electron per atom in the event of current flow (X₂+2e⁻->2X⁻, cathodic reduction),
c) the halogen ions (X⁻), which carry one negative charge, enter the electrolyte (18) from the cathode (16), which is in contact therewith,
d) the hydrogen molecules (H₂) are adsorbed, dissociated, and absorbed by the anode (14) and, in the event of current flow, give up one electron per atom (2H->2H⁺+2e⁻, anodic oxidation),
e) the hydrogen ions (H⁺), which carry one positive charge, enter the electrolyte (18) from the anode (14), which is in contact therewith,
f) hydrogen halide (HX), which then passes into the gas-tight chamber (10), forms directly or indirectly in the electrolyte (18), and
g) the steps a) to f) repeat in the event of current flow.

20. The method according to claim 19, characterized in that hydrogen (H₂) and halogen (X₂) are continuously supplied to the electrochemical cell (12) and hydrogen halide (HX) is continuously removed from the electrochemical cell (12).

21. The method according to claim 19 or 20, characterized in that energy in the form of heat (Δ) and/or radiation (hν) is continuously supplied to the gas-tight chamber (10), in order to maintain a specific equilibrium state.

22. The method according to one of claims 19 to 21, characterized in that hydrogen bromide (HBr) or hydrogen iodide (HI) are used as the hydrogen halide (HX).

23. The method according to one of claims 19 to 22, characterized in that hydrogen halide (HX) formed in the electrolyte (18) passes into the gas-tight chamber (10) from the electrolyte (18) because it is not soluble in the electrolyte (18).

24. The method according to one of claims 19 to 23, characterized in that a halogen-resistant vessel is used as the gas-tight chamber (10), via whose walls heat and/or radiation energy (Δ, hν) is supplied.

25. The method according to claim 24, characterized in that the vessel includes a radiation-transparent and thermally-insulated hood (22) and a heat-transparent floor (24), radiation energy (hν) mainly being supplied via the hood (22) and heat energy (Δ) mainly being supplied via the floor (24).

26. The method according to claim 24 or 25, characterized in that the surroundings of the vessel are designed so that an accumulation of heat results.
